(19) United States
(12) Patent Application Publication
(10) Pub. No.: US 2017/0005131 A1
(43) Pub. Date: Jan. 5, 2017

(54) IMAGE SENSOR

(71) Applicants: Rayence Co., Ltd., Gyeonggi-do (KR); VATECH EWOO Holdings Co., Ltd., Gyeonggi-do (KR)

(72) Inventors: Bong Jo JUNG, Gyeonggi-do (KR); Kang Min HWANG, Gyeonggi-do (KR)

(73) Assignees: Rayence Co., Ltd., Gyeonggi-do (KR); VATECH EWOO Holdings Co., Ltd., Gyeonggi-do (KR)

(21) Appl. No.: 15/197,888

(22) Filed: Jun. 30, 2016

(30) Foreign Application Priority Data
Jun. 30, 2015 (KR) 10-2015-0093307

(51) Int. Cl. H01L 27/146; G01T 1/20

(52) U.S. Cl. CPC H01L 27/14676; H01L 27/14609; G01T 1/20

(57) ABSTRACT

Disclosed is a method for driving an image sensor based on an automatic trigger method, in which pixels are arranged in the form of a matrix along row lines and column lines. The method includes, during an X-ray sensing period, continuously applying a gate signal having a turn-on level to all of the row lines of the image sensor and periodically reading out data from the all of the row lines; determining whether an X-ray is radiated by comparing the periodically read out data with reference data; generating a trigger signal when it is determined that an X-ray is radiated; and acquiring image data, generated by radiating the X-ray, according to the trigger signal.

### CROSS REFERENCE TO PRIOR APPLICATION

The present application claims priority under 35 U.S.C. §119 to Korean Patent Application No. 10-2015-0093307 (filed on Jun. 30, 2015).

### BACKGROUND OF THE INVENTION

Field of the Invention

The present invention relates generally to an image sensor and, more particularly, to an automatic trigger-based image sensor, which is capable of automatically determining whether an X-ray is radiated.

Description of the Related Art

A digital image sensor is a device for detecting an external optical image signal and converting it into an electrical signal. Particularly, the digital image sensor is mainly used for an X-ray imaging device.

In the image sensor, pixels, each of which is a unit for detecting an X-ray, are arranged in the form of a matrix along row lines and column lines. Here, each of the pixels has a photoelectric conversion element for converting the X-ray radiated from an X-ray radiation device into an electrical signal.

Generally, the X-ray radiation device and the image sensor communicate with each other in order to transmit a synchronization signal -informing the radiation of an X-ray to the image sensor. When such a synchronization signal is generated and transmitted, the image sensor may acquire an image by reading out image data, which are the electrical signals generated from the radiated X-ray, according to the synchronization signal.

However, depending on the environment in which the imaging device is used, the communication between the image sensor and the X-ray radiation device may be interrupted. In this case, an automatic trigger method, in which the image sensor itself checks whether an X-ray is radiated and automatically triggers the operation thereof when it is determined that the X-ray is radiated, is used.

In a conventional automatic trigger method, pixel data are read out on a per-row line basis and an automatic trigger signal is generated based on the read out data. This method is advantageous in that whether an X-ray is radiated can be checked based on a row line.

However, according to the method in which an automatic trigger signal based on a row line is used, because there may be a difference in the magnitudes of charges respectively accumulated in an upper region and a lower region, which are divided based on the row line from which a trigger signal is generated, image discordance between the two regions may result.

Also, whether to generate a trigger signal is determined depending on the magnitudes of charges accumulated in a single row line, but the magnitudes are not so high. Accordingly, there may be an error in which charges generated due to an external shock or an electromagnetic wave may erroneously generate a trigger signal and an image may be acquired in response to the erroneous trigger signal.

The foregoing is intended merely to aid in the understanding of the background of the present invention, and is not intended to mean that the present invention falls within the purview of the related art that is already known to those skilled in the art.

### SUMMARY OF THE INVENTION

The present invention is intended to increase the reliability of an image sensor by solving the problem of image discordance or erroneous acquisition of an image due to the external environment when an image sensor based on an automatic trigger method is used.

In order to achieve the above object, the present invention provides an image sensor, which includes a photoelectric conversion panel in which pixels are arranged in a form of a matrix along row lines and column lines; a gate drive circuit for continuously applying a gate signal to all of the row lines of the photoelectric conversion panel at a turn-on level for an X-ray sensing period; a data drive circuit for periodically reading out data from all of the row lines during the X-ray sensing period; and a light radiation determination unit for determining whether an X-ray is radiated by comparing the periodically read out data with a reference data, and generating a trigger signal when it is determined that the X-ray is radiated.

Here, image data, generated by radiating the X-ray in a charge accumulation period, are accumulated in the pixels in response to the trigger signal, and the data drive circuit may read out the image data accumulated in the pixels.

In response to the trigger signal, the gate drive circuit may simultaneously apply a gate signal to all of the row lines at a turn-off level.

In response to the trigger signal, the gate drive circuit may sequentially apply a gate signal to all of the row lines at a turn-off level.

When the data are read out during the X-ray sensing period, the pixels may be flushed.

According to an embodiment of the present invention, all of the row lines of an image sensor are configured to be handled identically such that all of the row lines are simultaneously selected and data are simultaneously read out therefrom during an X-ray sensing period and such that all of the row lines are simultaneously closed during a charge accumulation period. Accordingly, the problem with the conventional method, in which image discordance is caused based on the row line from which a trigger signal is generated when whether an X-ray is radiated is detected on a per-row line basis, may be solved. Furthermore, there is no need to perform offset calibration for solving the image discordance between the upper region and lower region, which are divided based on the row line from which a trigger signal is generated.

Also, in an embodiment of the present invention, because whether an X-ray is radiated is detected using the magnitudes of charges accumulated in all the row lines, erroneous detection of X-rays attributable to external shocks or electromagnetic waves may be prevented, thus preventing errors when acquiring an image.

Also, in an embodiment of the present invention, when a trigger signal is generated by the radiation of an X-ray, a gate signal applied to each of the row lines is sequentially switched to a turn-off level from the time point at which the trigger signal is generated. Accordingly, the generation of an offset-level difference between the row lines may be prevented, whereby a high-quality X-ray image may be acquired.

Consequently, an image sensor based on an automatic trigger method according to an embodiment of the present invention may exhibit improved reliability.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a mimetic diagram schematically illustrating an imaging device using an image sensor according to a first embodiment of the present invention;

FIG. 2 is a block diagram schematically illustrating an image sensor according to the first embodiment of the present invention;

FIG. 3 is a view illustrating the timing of application of a gate signal for driving an image sensor according to the first embodiment of the present invention;

FIG. 4 is a view illustrating another timing of application of a gate signal for driving an image sensor according to the first embodiment of the present invention;

FIG. 5 is a view illustrating the timing of application of a gate signal for driving an image sensor according to a second embodiment of the present invention; and

FIG. 6 is a view illustrating another timing of application of a gate signal for driving an image sensor according to the second embodiment of the present invention.

### DETAILED DESCRIPTION OF THE INVENTION

Hereinafter, an embodiment of the present invention will be described in detail with reference to the accompanying drawings.

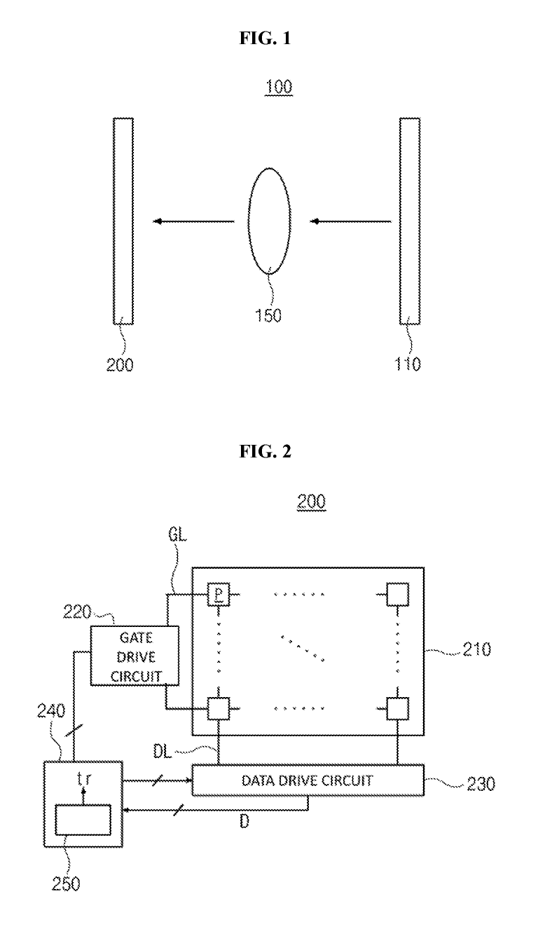

FIG. 1 is a diagram schematically illustrating an imaging device using an image sensor according to a first embodiment of the present invention, and FIG. 2 is a block diagram schematically illustrating an image sensor according to the first embodiment of the present invention.

As an imaging device 100 according to the first embodiment of the present invention, an imaging device that acquires images by radiating various forms of light, such as X-rays, visible light, and the like, may be used, but an X-ray imaging device for acquiring X-ray images is taken as an example for the convenience of description.

The imaging device 100 may include an X-ray radiation device 110 for generating an X-ray and radiating it onto an object to be checked 150, and an image sensor 200 for detecting the X-ray, having passed through the object 150.

Here, the image sensor 200 is a sensor that operates through an automatic trigger method, in which whether an X-ray is radiated is autonomously detected and a trigger signal tr is generated based on the result of detection. Accordingly, the image sensor 200 does not need to communicate with the X-ray radiation device 110 for transmission of a synchronization signal.

Meanwhile, as the image sensor 200, an image sensor using a direct conversion method, in which an X-ray is directly converted into an electrical signal, or an image sensor using an indirect conversion method, in which an X-ray is converted into visible light and the visible light is converted into an electrical signal, may be used.

Here, when the image sensor using an indirect conversion method is used, the image sensor 200 includes a scintillator for converting an X-ray into visible light. Here, the scintillator may be constituted by Cesium Iodide (CsI), but the scintillator is not limited thereto.

Referring to FIG. 2, the image sensor 200 may include a photoelectric conversion panel 210 and a drive circuit unit.

The photoelectric conversion panel 210 serves to convert incident light into an electrical signal. In the photoelectric conversion panel 210, multiple scanning lines, which are gate lines GL, extend along a row direction, and multiple reading out lines, which are data lines DL, extend along a column direction. Also, pixels P, each being a unit that performs a function of photoelectric conversion, are arranged in the form of a matrix along multiple row lines and column lines and are connected with the corresponding gate lines and data lines.

Each of the pixels P includes a switching element, which is connected with the gate line GL and the data line DL, and a photoelectric conversion element, such as a photodiode, which is electrically connected with the switching element.

The photoelectric conversion element converts incident light into an electrical signal. When the switching element is turned on, the electrical signal, which is data D, is output to the data line DL.

The drive circuit unit may include a gate drive circuit 220, a data drive circuit 230, a control circuit 240, and a light radiation determination unit 250.

The control circuit 240 controls the operation of the gate drive circuit 220 and data drive circuit 230 by outputting control signals thereto. Meanwhile, the control circuit 240 receives the read out data D from the data drive circuit 230, and may deliver the data D on a per-frame basis to an image processing circuit outside the image sensor 200.

The gate drive circuit 220 controls the timing of output of a gate signal according to the gate control signal supplied from the control circuit 240. For example, during a data reading out period for acquiring an X-ray image, the gate drive circuit 220 sequentially scans the gate lines GL, that is, applies a gate signal, which is a scan signal having a turn-on level, to each of the gate lines. Accordingly, a row line is sequentially selected and turned on, and data D stored in the pixels P located in the selected row line are output to the data line DL corresponding thereto.

Meanwhile, according to the present embodiment, during an X-ray sensing period for determining whether an X-ray is radiated, the gate drive circuit 220 may output a gate signal having a turn-on level to all the gate lines GL. In this case, all of the row lines are simultaneously selected and turned on, and the data D accumulated in the pixels of all of the row lines are simultaneously read out via the corresponding data lines DL.

The operation of the data drive circuit 230 is controlled based on the data control signal supplied from the control circuit 240. The data drive circuit 230 read outs the data accumulated in the pixels P. The read out data D are delivered to the control circuit 240.

The light radiation determination unit 250 determines whether an X-ray is radiated, and may generate a trigger signal tr for acquiring an X-ray image when it is determined that an X-ray is radiated. In response to the generated trigger signal tr, the control unit 240 controls the operation of the gate drive circuit 220 and data drive circuit 230 and thereby acquires image data generated by the radiated X-ray.

In the present embodiment, the case in which the light radiation determination unit 250 is included in the control unit 250 is taken as an example for the convenience of description. However, the light radiation determination unit 250 may be located outside the control unit 240, or may be included in the data drive circuit 230.

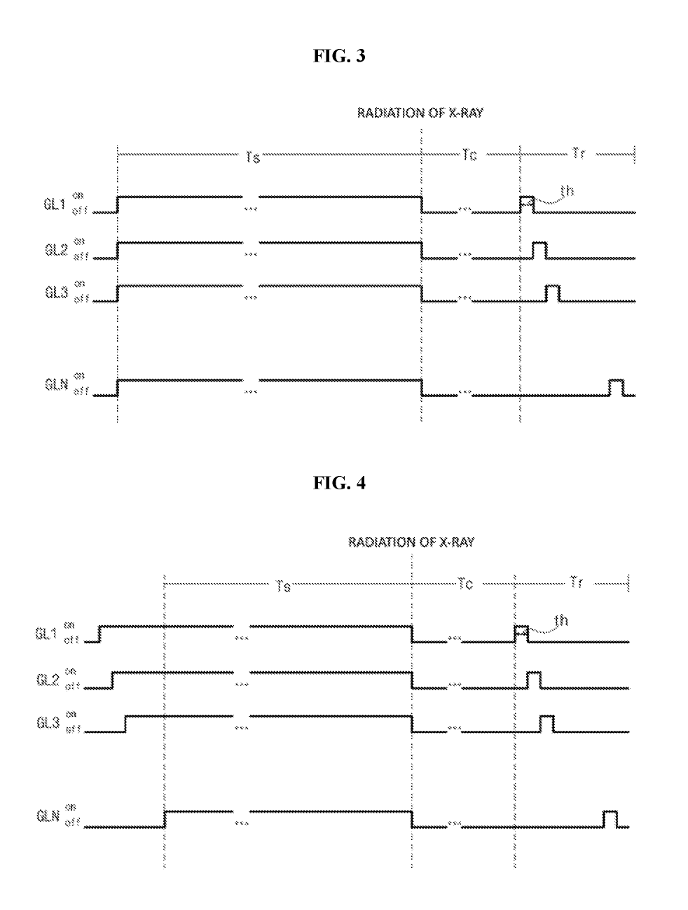

Hereinafter, a method for determining whether an X-ray is radiated and acquiring an image using the image sensor 200, which is configured as described above, will be described in detail with reference to FIG. 3.

FIG. 3 is a view showing the timing of application of a gate signal for driving an image sensor according to a first embodiment of the present invention.

As illustrated in the drawing, during an X-ray sensing period Is for determining whether an X-ray is radiated, a gate signal having a turn-on level is applied continuously and consistently to the gate lines GL1 to GLN, located in all of the row lines from a first row line to an N-th row line. In other words, the gate drive circuit 220 continuously outputs a gate signal having a turn-on level during the X-ray sensing period Ts.

Meanwhile, during the X-ray sensing period Ts, the data drive circuit 230 periodically read outs data accumulated in the pixels of all of the row lines via the data lines DL. The interval during which data are read out within the X-ray sensing period Ts is a very short time period compared to the X-ray sensing period Ts. For example, it may be set to have the same length as a horizontal period th within an image data reading out period Tr, but it is not limited thereto, and it may be shorter or longer than the horizontal period th.

Meanwhile, in the present embodiment, it is desirable to configure the pixels P such that a flushing process, that is, a process of eliminating dark charges from the pixels P, is performed through the process of reading out data during the X-ray sensing period Ts, without being limited thereto.

During the X-ray sensing period Ts, the data read out by the data drive circuit 230 may be sent to the light radiation determination unit 250.

The light radiation determination unit 250 compares the received data with reference data and thereby determines whether an X-ray is radiated. In this regard, for example, when the amount of read out data is greater than the amount of reference data, it is determined that an X-ray is radiated, whereas when the amount of read out data is equal to or less than the amount of reference data, it is determined that an X-ray is not radiated.

When it is determined that an X-ray is radiated, the light radiation determination unit 250 generates a trigger signal tr.

Conversely, when it is determined that an X-ray is not radiated, a trigger signal tr is not generated and the process of reading out data and the process of comparing the read out data with reference data may be repeatedly performed.

Meanwhile, when a trigger signal tr is generated, the control circuit 240 controls the output of the gate drive circuit 220 so as to output a gate signal having a turn-off level during a certain period, that is, during a charge accumulation period Tc, in response to the trigger signal tr. Also, the control circuit 240 interrupts the data reading out operation of the data drive circuit 230. Here, the charge accumulation period Tc is called a window.

Particularly, according to the present embodiment, during the charge accumulation period Tc, a gate signal having a turn-off level may be simultaneously output to all of the gate lines GL1 to GLN. Accordingly, the switching elements of the pixels P, located in all of the row lines, are simultaneously turned off, and thus the charges generated by the radiated x-ray, which are the image data, are accumulated in all of the row lines rather than being read out therefrom.

When the charge accumulation period Tc is terminated, the control circuit 240 may control the gate drive circuit 220 so as to sequentially output a gate signal having a turn-on level on a per-row line basis during the image data reading out period Tr.

Meanwhile, during the image data reading out period Tr, the data drive circuit 230 synchronizes with the gate signal, output on a per-row line basis, and read outs image data accumulated in the pixels P in the corresponding row line.

Then, the image data, read out on a per-row line basis, are delivered to the control circuit 240, whereby an X-ray image may be acquired.

As described above, according to the present embodiment, data are simultaneously read out from all of the row lines by simultaneously applying a gate signal having a turn-on level to all of the row lines during the X-ray sensing period, and a trigger signal is generated using the read out data. Then, when the trigger signal is generated, the reading out operation is interrupted by simultaneously applying a gate signal having a turn-off level to all of the row lines during the charge accumulation period. When the charge accumulation period is terminated, a gate signal having a turn-on level is sequentially output on a per-row line basis, whereby image data are read out from the corresponding row line.

As described above, in the present embodiment, all of the pixels are identically handled during the X-ray sensing period and the charge accumulation period. Accordingly, it is possible to solve the problem with the conventional method in which, when whether an X-ray is radiated is detected on a per-row line basis, image discordance between an upper region and a lower region, which are divided based on the row line from which a trigger signal is generated, is caused, because the time period during which charges are accumulated in the upper region is different from that in the lower region. Furthermore, in order to solve the problem of image discordance in the conventional method, an offset calibration process may be performed in the upper region and the lower region based on the row line from which the trigger signal is generated, but the present embodiment is advantageous in that this offset calibration process does not need to be performed.

Also, in the present embodiment, whether an X-ray is radiated is detected using the magnitudes of charges in all of the row lines. In this case, because the magnitudes of charges are greater than the magnitudes of charges in each of the row lines, which are used to detect whether an X-ray is radiated in the conventional method, erroneous detection of X-rays due to external shocks or electromagnetic waves may be prevented, thus preventing errors when acquiring an X-ray image.

Therefore, the image sensor based on an automatic trigger method according to the present embodiment may have improved reliability.

Meanwhile, an example in which the same gate signal having a turn-off level is applied to all of the row lines prior to entry into the X-ray sensing period Ts has been described. However, in another example, a gate signal having a turn-on level may be sequentially applied to the row lines prior to entry into the X-ray sensing period Ts, as illustrated in FIG. 4.

FIG. 5 illustrates the timing of application of a gate signal for driving an image sensor according to a second embodiment of the present invention.

The image sensor of the second embodiment may be configured to have the same components as the image sensor 200 of the first embodiment.

Meanwhile, referring to the timing of application of a gate signal according to the second embodiment, when a trigger signal is generated by the radiation of the X-ray, a gate signal applied on a per-row line basis may be sequentially switched to a turn-off level (that is, the gate signal falls to the turn-off level) from the time point at which the trigger signal is generated (from the start of the charge accumulation period).

In this case, the actual time period during which charges are accumulated, that is, the time period toff, during which a signal having a turn-off level is applied between the time at which the X-ray is radiated and the time at which image data are read out, is the same for all of the row lines.

Accordingly, the generation of an offset-level difference between the row lines may be prevented, whereby a high-quality X-ray image may be acquired.

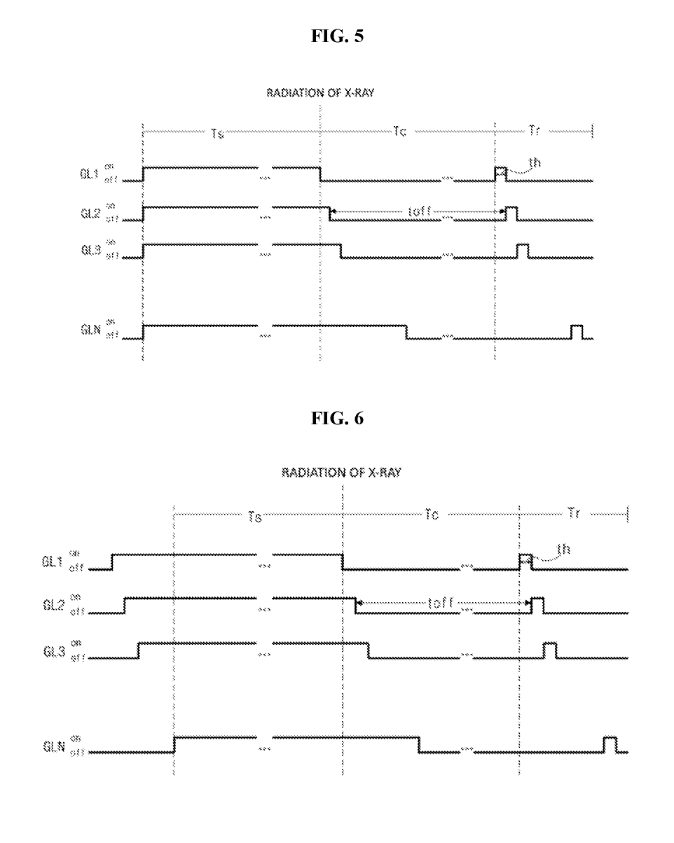

Meanwhile, the present embodiment may be configured such that the gate signal, switched from a turn-off level to a turn-on level, is sequentially applied to the row lines prior to entry into the X-ray sensing period, as illustrated in FIG. 6.

As described above, according to an embodiment of the present invention, all of the row lines are configured to be handled identically such that all of the row lines are simultaneously selected and data are simultaneously read out therefrom during the X-ray sensing period Ts, and then all of the row lines are simultaneously closed during the charge accumulation period Tc. Accordingly, the problem with the conventional method, in which image discordance is caused based on the row line from which a trigger signal is generated when whether an X-ray is radiated is detected on a per-row line basis, may be solved. Furthermore, the present invention is advantageous in that there is no need to perform an offset calibration process in the upper region and the lower region, which are divided based on the row line from which a trigger signal is generated.

Furthermore, in an embodiment of the present invention, because whether an X-ray is radiated is detected using charges in all of the row lines, erroneous detection of X-rays, which may be caused by external shocks or electromagnetic waves, may be prevented, thus preventing errors when acquiring an X-ray image.

Also, in an embodiment of the present invention, when a trigger signal is generated by the radiation of an X-ray, a gate signal may be configured to sequentially be switched to a turn-off level on a per-row line basis from the time point at which the trigger signal is generated. Accordingly, the generation of an offset-level difference between row lines is prevented, whereby an X-ray image having higher quality may be acquired.

Consequently, the image sensor based on an automatic trigger method according to an embodiment of the present invention may have improved reliability.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. An image sensor, comprising:
a photoelectric conversion panel in which pixels are arranged in a form of a matrix along row lines and column lines;
a gate drive circuit for continuously applying a gate signal to all of the row lines of the photoelectric conversion panel at a turn-on level for an X-ray sensing period;
a data drive circuit for periodically reading out data from all of the row lines during the X-ray sensing period; and
a light radiation determination unit for determining whether an X-ray is radiated by comparing the periodically read out data with a reference data and generating a trigger signal when it is determined that the X-ray is radiated.

2. The image sensor of claim 1, wherein image data, generated by radiating the X-ray, are accumulated in the pixels in response to the trigger signal, and
the data drive circuit reads out the image data accumulated in the pixels.

3. The image sensor of claim 2, wherein the gate drive circuit simultaneously applies a gate signal to all of the row lines at a turn-off level in response to the trigger signal.

4. The image sensor of claim 2, wherein the gate drive circuit sequentially applies a gate signal to all of the row lines at a turn-off level in response to the trigger signal.

5. The image sensor of claim 1, wherein when the data are read out during the X-ray sensing period, the pixels are flushed.
